(19) United States
(12) Patent Application Publication
(10) Pub. No.: US 2026/0173296 A1
(43) Pub. Date: Jun. 18, 2026

(54) SPLIT BACKPLANE CONNECTION DESIGN WITH HIGH SPEED INTERCONNECT

(71) Applicant: BAE Systems Information and Electronic Systems Integration Inc., Nashua, NH (US)

(72) Inventors: Katie Hugh, Brookline, NH (US); Jack T. Nigro, Nashua, NH (US); Ryan A. Walsh, Portsmouth, NH (US); Christopher A. Metildi, Pelham, NH (US)

(73) Assignee: BAE Systems Information and Electronic Systems Integration Inc., Nashua, NH (US)

(21) Appl. No.: 18/978,529

(22) Filed: Dec. 12, 2024

(51) Int. Cl. H05K 7/14

(52) U.S. Cl. CPC H05K 7/1451

(57) ABSTRACT

A configurable communications route for a backplane system provides the ability to install the backplane assembly into multiple platform specific system configurations. This allows for customization of desired communication paths, allowances for differing system implementations and the ability to expand a system over time. Additionally, a core backplane may reduce cycle time and cost, while increasing system reliability. This enables core backplane documentation lists, customizations, and connections to be utilized in various configurations. Outside of the core backplane usage, a multiple backplane configurable data path system allows for different mounting and mating options, increased system data communication speeds, and module changes and upgrades without mating interface changes, The backplane assembly has a variety of interconnects, including high speed communications that provide a flexible and modular design.

### TECHNICAL FIELD

The present disclosure relates generally to backplanes in the context of computer processing hardware, such as a printed circuit board that connects and interconnects various removable hardware components within an electronic device.

### BACKGROUND ART

A backplane in the context of electronic hardware is a physical or logical framework that connects and interconnects various hardware components within a computer or other electronic device. It serves as a central backbone or infrastructure for the communication and integration of different modules, cards, or devices within an electronic system.

The backplane typically includes a set of slots, connectors, and traces that allow various hardware components, such as expansion cards, to be connected and communicate with each other. The primary purpose of a backplane is to facilitate communication and data transfer between different hardware components, like central processing units (CPUs), memory modules, input/output (I/O) devices, and other peripherals. The backplane contains slots, which are receptacles for plugging in the aforementioned hardware components. These cards can include processors, network interfaces, and more. Backplanes typically define a specific bus architecture, which is the communication protocol and arrangement of signals used for data transfer and control between the components plugged into the slots. Backplanes may also incorporate power distribution systems to provide power to the connected components.

Those having skill in the art understand and appreciate that a backplane is different than a motherboard or a daughter card. The backplane primarily serves as a centralized interconnectivity infrastructure. It provides the physical and electrical connections between various hardware components, enabling communication and data transfer between them. The backplane is often used in systems that require modularity and flexibility, allowing for easy expansion and customization by adding or replacing components. The backplane can also be utilized to reduce weight and physical space from cable connectivity. The backplane typically connects expansion cards, modules, or other hardware components, facilitating communication and interaction between them. It may also include power distribution systems. Backplanes are often designed as a separate module or structure, allowing for customization and scalability. They contain slots or connectors where expansion cards or modules can be inserted. The backplane is usually a separate component that can be installed into a compatible enclosure or chassis to build an electronic system.

Conversely, the motherboard, also known as the mainboard or system board, is the central printed circuit board (PCB) that houses and connects essential components of a computer system, including the CPU, memory, storage devices, expansion slots, connectors, and power supply connections. It provides the foundation for the entire system to function by coordinating communication and data transfer between the different components. The motherboard connects all critical components directly to it, including the CPU, RAM, storage devices (like hard drives or SSDs), expansion cards (e.g., graphics cards, network cards), and various connectors (e.g., USB ports, audio jacks). The motherboard is a single, integrated PCB that is a standard, non-customizable component in a computer. It has a specific layout and configuration of components based on industry standards. The motherboard is a fundamental part of a computer system and is integrated into the computer case, serving as the central hub for all components.

A daughter card is different than a backplane. A daughter card is a smaller circuit board that connects to the main board (like a motherboard or a backplane). It extends or enhances the functionality of the main board by providing additional features, interfaces, or processing capabilities. Daughter cards are designed to plug into specific connectors on the main board. Daughter cards are smaller in size and are designed to fit into specific slots or connectors on the main board (e.g., backplane or motherboard). They can be thought of as extensions or add-ons to the system. A daughter card can provide functionality or extend the capabilities of the system by adding specialized features or functions. It may contain additional processors, memory, communication interfaces, or other specialized components. Daughter cards have connectors that are a mating interface to connectors on the backplane or motherboard. These connectors ensure proper alignment and electrical connection when plugging the daughter card into the respective slot.

Backplanes can vary in design and complexity based on the type of electronic system. In the context of a backplane, a module refers to a connectable (and sometimes removable) hardware component that can be inserted into one of the slots or connectors on the backplane. These modules are designed to provide, enhance, or expand the functionality of the system. A module is a physical unit that can be added or removed from the backplane. It is often a circuit board or card that contains specific functionalities or features. The backplane provides the physical and electrical connections needed to integrate these modules into the overall system. Modules are inserted into slots or connectors on the backplane. These slots are designed to match the size and specifications of the modules, ensuring a secure and compatible fit. Modules can have various functionalities, depending on the purpose of the system and the intended application. When a module is inserted into the backplane, it establishes connections with other components in the system, such as the CPU, memory, and other modules. The backplane facilitates communication and data transfer between these interconnected components. Using modules allows for system scalability and flexibility. It enables users to customize the system based on their specific requirements by adding or replacing modules without requiring significant changes to the overall hardware infrastructure. Depending on the design and purpose, modules may be “hot-swappable,” meaning they can be added or removed while the system is running without disrupting its operation.

U.S. Pat. No. 10,665,975 teaches a connector having a connector body and three connecting ends disposed on the connector body. Signal interfaces inside a first connecting end are in communication with signal interfaces inside a second connecting end in a one-to-one correspondence. The first connecting end is connected to a backplane connector on a backplane. The second connecting end is connected to one end of a transmission cable, and the other end of the transmission cable is connected to a communications component on a target board. The backplane is configured to implement communication between boards, and the target board is any one of the boards. A third connecting end is configured to secure the connector body to the target board. The connector having three ends enables signals to be injected from a communication device into the backplane. The three ends of the connector allows for a daughter card connector to hook through a cable rather than a board. Effectively, this teaches a daughter card and backplane system using right angle backplane connectors, and using a cable to create high speed communications.

U.S. Pat. No. 10,579,574 (the '574 patent) teaches an instrumentation chassis that includes a backplane with multiple peripheral slots located on the backplane configured to receive insertable peripheral modules. There is at least one protocol agnostic high speed connection mounted on, but not electrically connected to the backplane. The high speed connection is configured to interconnect at least two peripheral modules in corresponding peripheral slots of the multiple peripheral slots, bypassing the backplane.

U.S. Patent Application Publication No. 2022/029649 (the '649 publication) teaches systems and methods for providing access to a wireless network include apparatus and manufacturing and configuration techniques. Embodiments of the reference includes a head-end configured to receive electrical power and communicate with the wireless network. In an embodiment, the '649 publication includes a plurality of integrated access points each comprise components such as a radio, a power supply, a controller, a network transceiver, and an antenna. The components of each integrated access point, whether or not they are assembled on one or more rigid or flexible cards, may be embedded in a material expanse such as a flexible strip, upon which each set of components may be proximally integrated. In an embodiment, the reference provides a system includes a unified backplane interconnect coupled to the head-end, the unified backplane interconnect comprising a plurality of interconnects. Each integrated access point may comprise a single radio, or more than one radio. Essentially, the reference is focused on the wireless aspect of communication.

U.S. Pat. No. 11,372,180 (the '180 patent) teaches a modular networking hardware platform that utilizes a combination of different types of units that are pluggable into cassette endpoints. The reference enables the construction of an extremely large system, e.g., 500 Tb/s+, as well as small, standalone systems using the same hardware units. The reference states that this provides flexibility to build different systems with different slot pitches. The hardware platform includes various numbers of stackable units that mate with a cost-effective, hybrid Printed Circuit Board (PCB)/Twinax backplane, that is orthogonally oriented relative to the stackable units. In contrast to the reference, exemplary embodiments of the present disclosure provide for the connection of modules within the split backplane assembly for EW modules as opposed to networking components, which has different configuration requirements.

U.S. Pat. No. 7,359,214 (the '214 patent) teaches an electronic system having a backplane designed for efficient routing of signal traces. The system of the reference includes two or more daughter cards that are connected to multiple other daughter cards in the system. These daughter cards are mounted centrally to the backplane in the system. Connections between those two daughter cards and the backplane are made through electrical connectors that are distributed in columns along the length of the daughter cards. The connectors are positioned with space between the connectors. The space forms routing channels such that signals that must be connected to the central cards from a daughter cards on either side may be routed through the routing channels. The reference has daughter cards that are plugged into the board to perform switching. Additionally, the reference limits the number of layers of the backplane to increase signal speeds.

U.S. Pat. No. 6,932,617 (the '617 patent) teaches a backplane system allowing a very large number of interconnections between high-connectivity printed circuit boards and a backplane. The backplane is fragmented into a plurality of backplane parts that comprise connectors on their edges to mate connectors arranged on the high-connectivity printed circuit boards. These backplane parts may also include other connectors on their edges to couple to extension printed circuit boards requiring less interconnections or cables. Interposers can be used to link several backplane parts and provide enhanced air circulation. The reference further provides for a hot swap functionality by installing or removing different cards.

### SUMMARY OF THE INVENTION

What is needed is an improved backplane assembly that offers a modular and scalable approach to building electronic systems. For example, connecting a hardwired complete backplane and module system to another complete backplane and module system involves lengthy redesign or expensive respins of circuit boards. Being able to concatenate or rearrange module systems at a higher level of assembly, or connecting a module from one backplane to another module on another backplane can save enormous amounts of time and money in design, build, fabrication, and test. Some challenges experienced in connecting modules from one system to modules in another system is that modules and backplanes are designed with specific physical form factors and connector types to ensure a secure and compatible connection. If the form factors or connectors don't match between the modules and backplanes, physical connection becomes impossible without custom adapters or modifications. Another factor in integrating various systems is variations in voltage levels, power requirements, and signal levels between different backplanes and modules, posing significant challenges in a single backplane solution. If the levels are not compatible, it may require additional components, such as voltage converters or level shifters, to make the connection work reliably. Further, some backplanes and modules may be customized or proprietary in their design, making it challenging to connect them with standard off-the-shelf components. Customized components might require special adapters or custom engineering to facilitate the connection. And yet another challenge would be to have a backplane system where the modules do not fit in a planar installation.

As technology advances and newer, more powerful components or modules are developed, the backplane assembly of the present disclosure can be designed to accommodate these upgrades by enabling high speed connections between different modules and backplane systems. In one embodiment of the present disclosure, a segmented or split backplane assembly composed of two or more separate backplanes functions as a single unit through a modular approach. This design allows for shorter PCB routing channels, innovative rack layouts, common hardware, and off-the shelf product. The desire to reduce non-recurring engineering (NRE) and development times for multiple, similar uses is one driving need for this innovation. By creating a common design, economies of scale can be realized when this hardware is in production. This embodiment provides for the arrangement of the modules into separate backplane systems (instead of a monolithic backplane) coupled with high-speed digital cables/wires or flexprint connectors. This enables common backplane parts or components to be used on/in multiple uses and it also creates commonality in designs to reduce NRE, design and manufacture lead times, production schedule/cost, and test expenditures.

In one exemplary aspect, a backplane design for core modules with connectorized signals provides the ability to install one built and tested backplane assembly into multiple individual system configurations with a smaller ancillary design added for specific additional functionality. This then enables core backplane documentation lists customizations and connections to be utilized in various configurations. The exemplary split backplane assembly configuration with high speed interconnects provides a flexible and modular design over a single, monotonic printed circuit board design. This approach allows for shorter routing channels, innovative rack layouts, common hardware, and off-the shelf product. In one embodiment, routing lanes are located outside of a dual coldplate, standard single bay, single row module alignment in a rack. The multiple rows of modules or varying angles of installation can be achieved for cooling, space constraints, or other factors. Additionally, multiple instantiations of the same set of boards can be achieved with a quick change to cabling (simpler, faster, and less costly than new backplanes). The exemplary split backplane assembly configuration with high speed interconnects allows for “backwards compatibility” to have greater reach with the proper handling of growth capabilities. With the ability to change the connections in a board as different hardware is populated the user of the backplane of the present disclosure can upgrade signal speeds as well as module connectivity. At least one exemplary split backplane assembly configuration with high speed interconnects should permit high speed signals to be transmitted directly through to cables and bypass the backplane altogether to achieve >20Gbs speed, which may require a connector interface update to some modules.

In one aspect, an exemplary embodiment of the present disclosure may provide a split backplane assembly comprising a first backplane having a first plurality of electronic modules mounted thereon, and the first backplane having a first plurality of electical connectors, wherein at least one electrical connector from the first plurality of connectors is in electrical communication with at least one electronic module from the first plurality of electronic modules; a second backplane having a second plurality of electronic modules mounted thereon, and the second backplane having a second plurality of electrical connectors, wherein at least one electrical connector from the second plurality of connectors is in electrical communication with at least one electronic module from the second plurality of electronic modules; wherein the first backplane is physically spaced apart from the second backplane; wherein the first backplane is in selective electrical communication with the second backplane via at least one wire or cable selectively connected to a first electrical connector on the first backplane and a second electrical connector on the second backplane that electrically connects a first module on the first backplane to a second module on the second backplane.

This exemplary embodiment or another exemplary embodiment or another exemplary embodiment may further include a first electrical configuration in which the at least one wire or cable is connected to the first connector on the first backplane and the second connector on the second backplane; a second electrical configuration in which the at least one wire or cable is connected to the first connector on the first backplane and another second connector on the second backplane; wherein whether the split backplane assembly is in the first electrical configuration or the second electrical configuration is based on user-selected preference.

This exemplary embodiment or another exemplary embodiment or another exemplary embodiment may further include a third backplane having a third plurality of electronic modules mounted thereon, and the third backplane having a third plurality of electric connectors, wherein at least one connector from the third plurality of connectors is in electrical communication with at least one electronic module from the third plurality of electronic modules; and a user-selected electrical communication between the first backplane and at least one of the second backplane and the third backplane.

This exemplary embodiment or another exemplary embodiment or another exemplary embodiment may further include an electrical configuration in which the at least one wire or cable is connected to the first connector on the first backplane and the second connector on the second backplane, and another at least one wire or cable is connected to the second connector on the second backplane and the third connector on the third backplane. In one embodiment, the at least one electronic module on the first backplane communicates with the at least one electronic module on the third backplane directly by bypassing the second backplane. In another embodiment, the at least one electronic module on the first backplane communicates with the at least one electronic module on the third backplane indirectly by passing through the at least one module on the second backplane.

This exemplary embodiment or another exemplary embodiment or another exemplary embodiment may further include that the first backplane is housed within a first housing and any subsequent backplane can be housed within a different housing that is physically distinct from the first housing.

This exemplary embodiment or another exemplary embodiment or another exemplary embodiment may further include another wire or cable selectively connected between the at least one electric connector and another electric connector on the first backplane that electrically connects the first electronic module on the first backplane with another electronic module on the first backplane.

This exemplary embodiment or another exemplary embodiment or another exemplary embodiment may further include that the first plurality of electronic modules on the first backplane are electronic warfare (EW) modules.

This exemplary embodiment or another exemplary embodiment or another exemplary embodiment may further include lower layers in the first backplane, wherein the lower layers are routed for high speed signals.

This exemplary embodiment or another exemplary embodiment or another exemplary embodiment may further include that at least the first backplane is backdrilled.

This exemplary embodiment or another exemplary embodiment or another exemplary embodiment may further include that at least the first backplane includes a stripline design configured to achieve a balanced transmission line thereby reducing electromagnetic interference and crosstalk between neighboring traces.

### BRIEF DESCRIPTION OF THE DRAWINGS

Sample embodiments of the present disclosure are set forth in the following description, are shown in the drawings and are particularly and distinctly pointed out and set forth in the appended claims.

FIG. 1 (FIG. 1) is a diagrammatic pictorial representation of a split backplane assembly according to one exemplary embodiment of the present disclosure.

FIG. 2 (FIG. 2) is a diagrammatic pictorial representation of a split backplane assembly according to another exemplary embodiment of the present disclosure.

FIG. 3 (FIG. 3) is a diagrammatic pictorial representation of a split backplane assembly according to another exemplary embodiment of the present disclosure.

FIG. 4A (FIG. 4A) is an operational schematic view of a selective cabling arrangement of a split backplane assembly according to one exemplary embodiment of the present disclosure.

FIG. 4B (FIG. 4B) is an operational schematic view of a selective cabling arrangement of a backplane assembly according to another exemplary embodiment of the present disclosure that utilize only a single backplane.

FIG. 5A (FIG. 5A) is a flow chart depicting one exemplary method for assembly or fabrication of the split backplane assembly.

FIG. 5B (FIG. 5B) is flow chart depicting another exemplary method for assembly or fabrication of a backplane assembly that utilizes only a single backplane.

Similar numbers refer to similar parts throughout the drawings.

### DETAILED DESCRIPTION

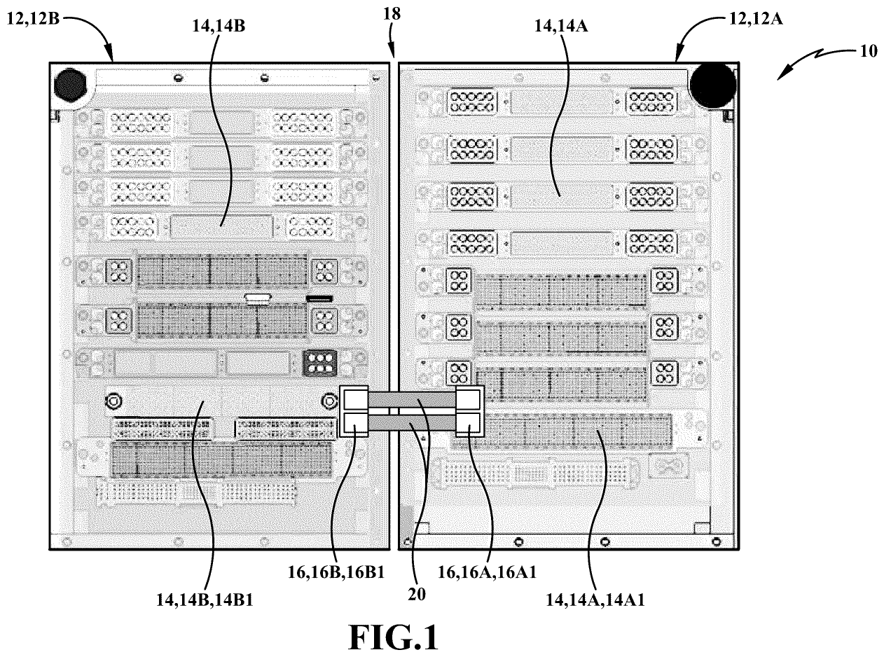

FIG. 1 through FIG. 4 depict a split backplane assembly generally at 10. Backplane assembly 10 may include a plurality of backplanes 12. On each of the backplanes 12, there may be a plurality of electronic modules 14. There may also be a plurality of electrical connectors 16. Each of the electrical connectors 16 is in electrical communication with at least one of the modules 14.

Backplanes 12 may be constructed from any suitable material. In one example, backplanes may be constructed from rigid materials like fiberglass-reinforced epoxy laminate (FR-4), which is a common type of printed circuit board (PCB) material. FR-4 provides a balance of rigidity, durability, and electrical properties. In this example, or other examples, backplanes 12 often comprise multiple layers of PCBs laminated together. Each layer contains conductive traces and insulating layers. The layers are interconnected through plated through-holes (vias) to establish the necessary electrical connections. The layer stackup may define the arrangement of conductive layers, insulating layers, and other materials in the backplane. The stackup may vary based on the user-selected design requirements, such as the number of layers needed for routing signals. There may be ground and power planes on each of the backplanes 12. Backplanes 12 may have specific routing channels or traces dedicated to high-speed signals, power distribution, and critical data paths. These routing channels are carefully designed to maintain controlled impedance, low loss, and reduce crosstalk. Although the most common shape for backplane 12 is rectangular because this shape provides a convenient configuration for slotting in various modules 14, the backplane 12 may be formed in any shape or perimeter configuration. The dimensions and aspect ratio of backplane 12 are determined based on the enclosure or housing for assembly 10 and the number of slots or modules 14 required to meet the application specific need or user-selected concatenated operation of assembly 10. The size of backplanes 12 can vary based on the application, ranging from smaller configurations for compact devices to larger configurations for more complex systems. Backplanes 12 have slots or connectors 16 arranged in specific patterns to accommodate various signaling options from modules 14. The number and density of connectors 16 or modules 14 on the backplanes 12 depend on the application's scalability and the number of modules that need to be accommodated. Additionally, the number of connectors 16 is based on the variability desired in the system 10.

In one example, there may be a first backplane 12A and a second

backplane 12B. The first backplane 12A has a first plurality of electronic modules 14A mounted thereon. The first backplane 12A has a first plurality of electric connectors 16A. At least one electric connector from the first plurality of connectors 16A is in electrical communication with at least one electronic module from the first plurality of electronic modules 14A. There may be a second backplane 12B having a second plurality of electronic modules 14B mounted thereon. The second backplane has a second plurality of electric connectors 16B. At least one electric connector from the second plurality of connectors 16B is in electrical communication with at least one electronic module from the second plurality of electronic modules 14B. In one particular embodiment, the first backplane 12A is physically spaced apart from the second backplane 12B defining a gap 18 therebetween. The gap 18 between may be of any size and distance depending on the specific application and purpose of the operation between the backplanes. When the backplanes are part of the assembly 10 that is installed in a smaller form factor electronic system, the gap 18 may be smaller than what could be utilized in a larger form factor electronic system. In one embodiment, the gap 18 extends entirely between the first and second backplanes 12A, 12B such that the gap is uninterrupted and continuous between the two backplanes. In the shown embodiment, the gap 18 is defined between two backplanes that are aligned side-by-side. However, it is to be understood that the backplanes could be spaced apart in a stacked relationship such that the gap is defined between opposing major surfaces of the two backplanes. Further, the gap can be empty or filled/occupied with an insulating material. Thus, the term gap 18 also includes a spaced apart relationship between backplaces with an insulator therebetween.

In one exemplary embodiment, the first backplane 12A is in selective electrical communication with the second backplane 12B via at least one wire or cable 20 selectively connected to a first electric connector 16A1 on the first backplane 12A and a second electric connector 16B1 on the second backplane 12B that electrically connects a first module 14A1 on the first backplane 12A to a second module 14B1 on the second backplane 12B. In this exemplary embodiment or another exemplary embodiment, the arrangement of cabling between modules on the first backplane 12A and the second backplane 12B can be connected or established based on a user-selected or system designer-selected operation of the assembly 10.

For example, the first backplane 12A may have modules 14A that are configured to perform standardized operations and the second backplane 12B may have modules 14B that perform specialized operations. Then, a user or system-designer may selectively choose which connectors 16 to connect with a cable or wire 20 to effectuate electrical communications between the standardized modules on the first backplane 12A with the specialized modules on the second backplane 12B. This allows the first backplane 12A to be manufactured and fabricated with a standard form factor for mass production thereby reducing NRE, then second backplane 12B can be selectively connected to perform a user-selected or system designer-selected function.

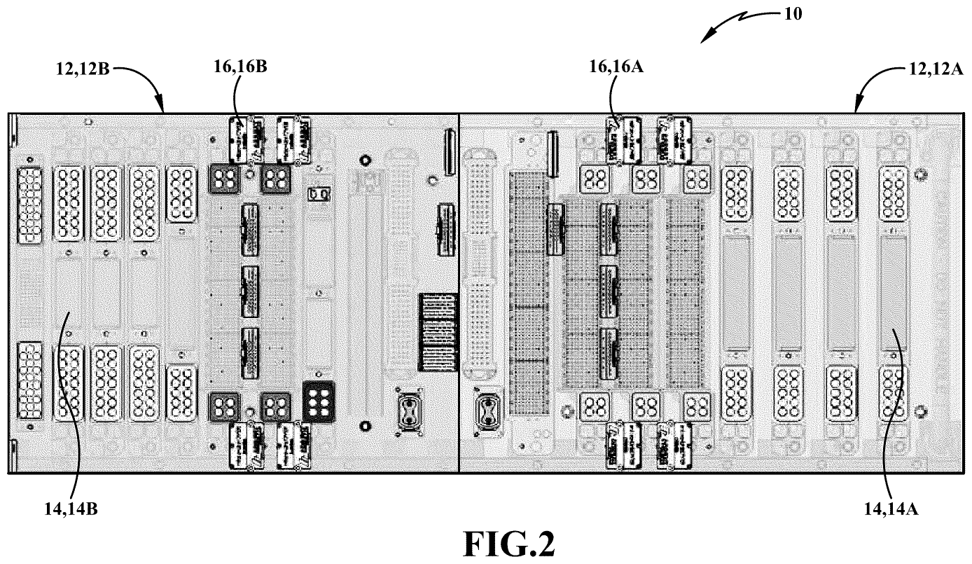

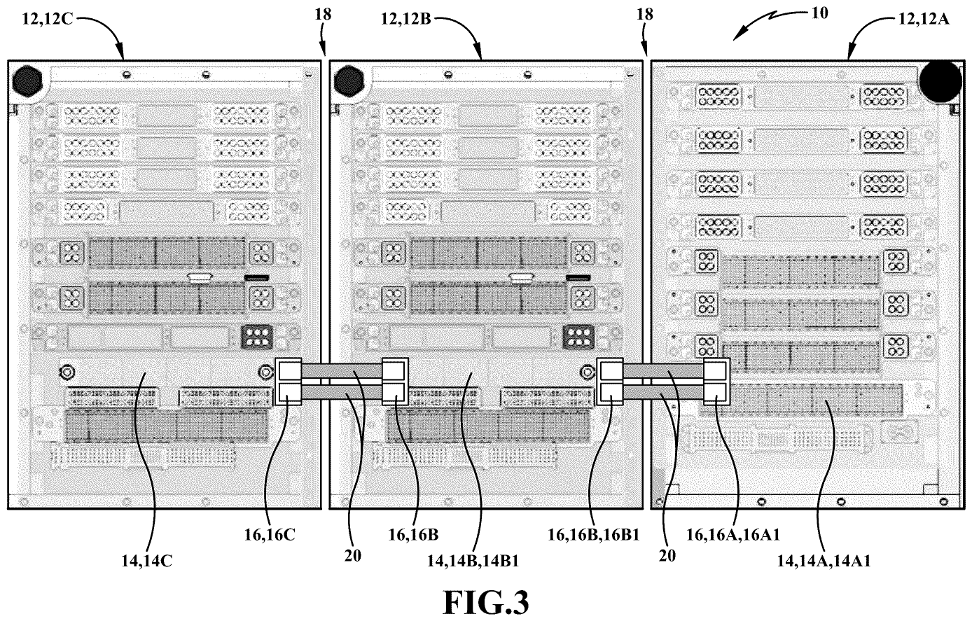

The first backplane 12A and second backplane 12B may be arranged in any manner that meets the application specific needs of assembly 10. For example, FIG. 1 depicts that the first backplane 12A and the second backplane 12B are arranged in a side-by-side relationship. FIG. 2 depicts that the first backplane 12A and the second backplane 12B are arranged in an end-to-end relationship. FIG. 3 depicts that three backplanes can be arranged in a side-by-side relationship. However, these arrangements are merely exemplary and any arrangement is possible to meet processing requirements and space constraints of assembly 10 in a computing system or electrical system, such as an electronic warfare (EW) system.

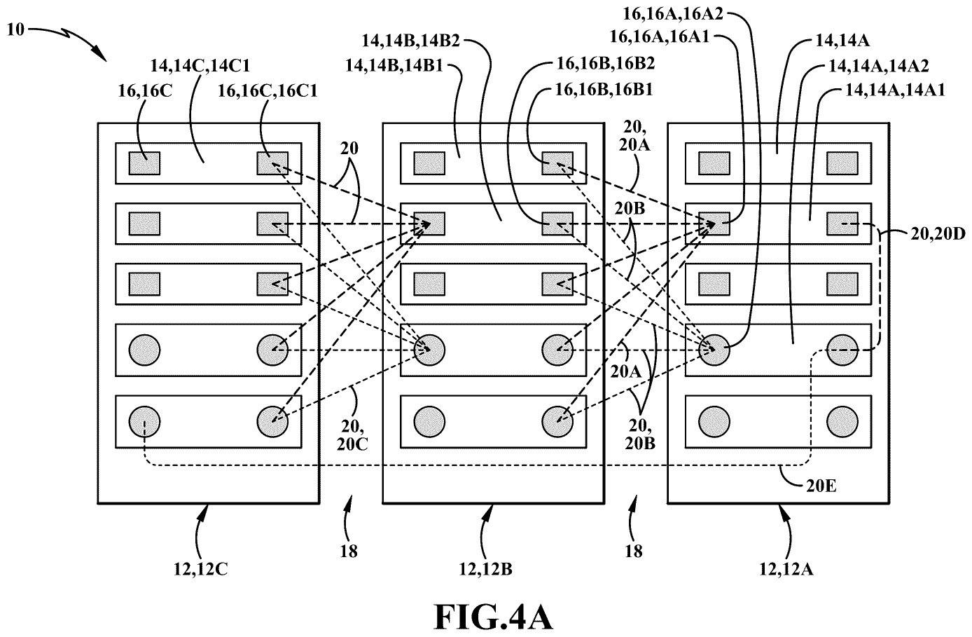

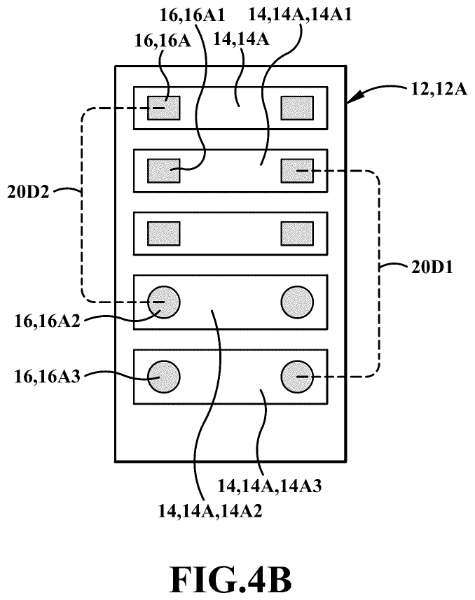

FIG. 4 depicts that the split backplane assembly 10 can be rearranged or

concatenated based on a user-selected or system designer-selected preference of module connection as shown by the dashed lines representing the cable(s) or wire(s) 20. For example, a first electrical configuration may be provided in which the at least one wire, flexprint or cable 20 is connected to the first connector 16A1 on the first backplane12A and the second connector 16B1 on the second backplane 12B. However, there is also a second electrical configuration in which the at least one wire, flexprint or cable 20 is connected to the first connector 16A1 on the first backplane 12A and another second connector 16B2 on the second backplane 12B. Whether the split backplane assembly 10 is in the first electrical configuration or the second electrical configuration is based on user-selected or system designer-selected preference.

In one particular example, and as shown in FIG. 4, a first wire, flexprint or cable 20A can be connected based on the user-selected or system-designer preference (i.e., selectively connected) of which modules 14 should connect together to perform a desired function. In this example, the first cable 20A is shown in dashed lines which represents that the wire, flexprint or cable 20A can connect the first connector 16A1 on the first module 14A1 with any of the respective connectors on the second backplane 12B. For example, wire, flexprint or cable 20A could connect with connector 16B1 or connector 16B2 and so on. Similarly, a second wire, flexprint or cable 20B can be connected based on a user-selected or system-designer preference (i.e., selectively connected) of which modules should connect together. In this example, the second cable 20B is shown in dashed lines which represents that the wire or cable 20B can connect the second connector 16A2 on the second module 14A2 with any of the respective connectors on the second backplane 12B. For example, wire, flexprint or cable 20B could connect with connector 16B1 or connector 16B2 and so on.

With continued reference to FIG. 4, the split backplane assembly 10 may additionally include a third backplane having a third plurality of electronic modules 14C mounted thereon, and the third backplane having a third plurality of electric connectors 16C, wherein at least one connector from the third plurality of connectors 16C is in electrical communication with at least one electronic module from the third plurality of electronic modules 14C. As shown by the dashed lines representing cables, flexprint or wires 20C, there is a user selected electrical communication between the first backplane 12A and at least one of the second backplane 12B and the third backplane 12C.

When the third backplane 12C is present in assembly 10, there is an electrical configuration in which the at least one wire, flexprint or cable 20A is connected to the first connector 16A1 on the first backplane 12A and the second connector 16B1 on the second backplane 12B, and another at least one wire or cable 20C is connected to the module 14B1 on the second backplane 12B and the third connector 16C1 on the third backplane 12C. In one particular embodiment, at least one electronic module 14A1 on the first backplane 12A communicates with the at least one electronic module 14C1 on the third backplane 12C directly by bypassing the second backplane 12B. For example, wire, flexprint or cable 20E could connect one of the connectors 16A with one of the connectors 16C. Yet in another particular embodiment, at least one electronic module 14A1 on the first backplane 12A communicates with the at least one electronic module 14C1 on the third backplane 12C indirectly by passing through the at least one module, such as module 14B1 or another, on the second backplane 12B.

In some exemplary instantiations, the split backplane assembly 10 can have at least one additional or another wire, flexprint or cable 20D selectively connected between the at least one electric connector and another electric connector on the first backplane 12A that electrically connects the first electronic module 14A1 on the first backplane with another electronic module 14A2 on the first backplane (i.e., both connectors on the same backplane).

FIG. 4B depicts another exemplary instantiation of the backplane assembly 10 in which only a single backplane 12 is utilized, such as first backplane 12A. When using only one backplane in assembly 10, there by be one or more wires, flexprints or cables that selectively connects at least one electric connector and another electric connector on the single backplane. For example, a first wire, flexprint or cable 20D1 is selectively connected between the at least one electric connector 16A1 and another electric connector 16A3 on the first backplane 12A that electrically connects the first electronic module 14A1 on the first backplane with another electronic module 14A3 on the first backplane (i.e., both connectors on the same backplane). A second wire, flexprint or cable 20D2 is selectively connected between the at least one electric connector 16A and another electric connector 16A2 on the first backplane 12A that electrically connects the first electronic module 14A on the first backplane with another electronic module 14A2 on the first backplane (i.e., both connectors on the same backplane). One exemplary advantage of utilizing only one backplane in assembly 10 is that it would allow certain high speed communications to be directed to different modules in the system of assembly 10, or on a single backplane 12, depending on what the system needs are for that bandwidth.

In some exemplary instantiations, the split backplane assembly 10 can be entirely housed within one housing, box or physical structure. However, in other exemplary instantiations, the backplanes 12 can be physical separated and housed within their own housings, boxes or physical structures and connected via a cable or wire extending between those respective housings, boxes or physical structures. For example, the first backplane 12A could be housed within a first housing and the second backplane 12B could be housed within a different second housing that is physically distinct from the first housing. This example highlights that assembly 10 does not need to be a monolithic backplane system or a card-to-card system. The electrical connection effectuated by cable or wires 20 in assembly 10 can be hard connectors, cables or flexprint. This allows the backplanes 12 of assembly 10 to be placed in any orientation with respect to each other and, in some exemplary embodiments, allows them to reside in different boxes as long as there is cabling between them.

Each backplane 12 of the assembly 10 of the present disclosure may provide for routing lower layers of the backplane 12 for high speed signals, backdrilling, choosing short-route connection points if possible, stripline design, loose coupling and adjusted routing for pinfields, removal of non-functional pads. More particularly, in the context of an EW system, designing a backplane with specific considerations such as routing lower layers for high-speed signals, backdrilling, short-route connection points, stripline design, loose coupling, adjusted routing for pinfields, or removal of non-functional pads offer several advantages related to signal integrity, performance, and overall system efficiency.

In one example, routing high-speed signals on lower layers of the backplane 12 allows for less stubbing without having to backdrill. For example, some exemplary signals that may be routed on the layers of the backplane include: high-speed differential pairs, used in interfaces like USB, PCIe, SATA, and HDMI, are commonly routed on the lower layers to maintain signal integrity and minimize interference; Serial buses such as PCI Express (PCIe), SATA, SAS (Serial Attached SCSI), and Ethernet often use differential signaling and are routed on lower layers to ensure consistent impedance and minimize signal degradation; high-speed memory interfaces, including DDR (Double Data Rate) buses (e.g., DDR3, DDR4, DDR5), are routed on the lower layers to maintain proper signal integrity and reduce noise; clock signals and related clock-derived signals, especially those operating at high frequencies, are routed on lower layers to minimize skew, maintain synchronization, and reduce interference; interfaces like parallel data buses (e.g., parallel memory buses) and high-speed parallel I/O (Input/Output) interfaces often use controlled impedance routing on the lower layers to ensure data integrity; Radio Frequency (RF) signals may be are routed on lower layers to maintain controlled impedance and prevent interference or signal loss; various high-speed bus interfaces within the system, such as AXI (Advanced eXtensible Interface) or other interconnects, may use the lower layers to ensure reliable and high-speed communication; High-frequency analog signals, such as those in RF circuitry or analog-to-digital converters (ADCs) and digital-to-analog converters (DACs), are routed on lower layers to maintain signal integrity and reduce noise; both control and data signals operating at high frequencies are often routed on the lower layers for improved performance and impedance matching. The exact speed or frequency of high-speed signals can vary based on the technology, standard, and application. Thus the term “high-speed” as used herein depends on the type of connection types utilized. For example, PCIe operates at different speeds, denoted by generations. The speeds for each PCIe generation (Gen) are approximately: PCIe Gen 1: Up to 2.5 GT/s (Giga-transfers per second); PCIe Gen 2: Up to 5 GT/s; PCIe Gen 3: Up to 8 GT/s; PCIe Gen 4: Up to 16 GT/s; and PCIe Gen 5: Up to 32 GT/s. The speeds for USB standards have evolved, and different versions have varying speeds, for example, USB 2.0: Up to 480 Mbps (Megabits per second); USB 3.0: Up to 5 Gbps; USB 3.1: Up to 10 Gbps; USB 3.2: Up to 20 Gbps; USB 4: Up to 40 Gbps. The SATA standards have also seen speed increases with different versions, for example SATA 1.0: Up to 1.5 Gbps; SATA 2.0: Up to 3 Gbps; SATA 3.0: Up to 6 Gbps; and SATA 3.2 (SATA Express): Up to 16 Gbps. Ethernet speeds can vary widely based on the standard and implementation, for example, Fast Ethernet (100 Base-T): Up to 100 Mbps; Gigabit Ethernet (1000 Base-T): Up to 1 Gbps; 10-Gigabit Ethernet: Up to 10 Gbps; 100-Gigabit Ethernet: Up to 100 Gbps. Memory interfaces like DDR3, DDR4, and DDR5 operate at speeds ranging from several gigabits per second (Gbps) to tens of gigabits per second. High-frequency analog and RF signals can range from megahertz (MHz) to gigahertz (GHz) and beyond, depending on the specific application.

Any of these signals can be transmitted along the wires, cables or flexprint 20 from one backplane to another. For example, any of the foregoing signals can move along the cables, wires or flexprint 20. In some particular embodiments, Low-Speed Digital Signals, (e.g., 0 V and 5 V or 3.3 V) may be used for basic digital communication between modules, and High-Speed Digital Signals may be used for faster data transfer rates and require careful design to maintain signal integrity (e.g., PCI or PCIe). Still further, analog signals, power signals, ground signals, serial signals or low voltage differential signal, control signals, clock signals, or any other type of signal identified herein or otherwise known can be transmitted between the backplanes along the wires, cables or flexprint 20 from one backplane to another

In another example, reduced signal reflection and transmission line effects may be accomplished by backdrilling any or all of the backplanes 12. Stated otherwise, at least one of the backplanes 12 may be backdrilled. Backdrilling is a technique used to remove excess material from vias, reducing impedance discontinuities and signal reflections. This helps maintain signal integrity and reduces transmission line effects, especially advantageous for high-frequency signals in EW systems.

In another example, optimized signal paths and low latency may be accomplished by selecting short and direct signal routes. This should minimizes signal travel time and latency. For high-speed signals in an EW system, this is advantageous for minimizing delays and ensuring rapid response to electronic threats.

In another example, signal isolation and interference reduction may be accomplished based on a stripline design or configuration. Stripline design helps in achieving a balanced transmission line, reducing electromagnetic interference and crosstalk between neighboring traces. It enables signals to be isolated and maintain their integrity throughout the backplane 12. A stripline design in one exemplary embodiment of the present disclosure may include a signal trace sandwiched between two ground planes, offering a balanced transmission line that is effective in minimizing signal degradation and interference. The layer structure of one exemplary stripline design may include Layer 1: Top signal layer (e.g., component side), Layer 2: Ground plane; Layer 3: Signal trace layer; and Layer 4: Bottom ground plane.

Regarding, one exemplary signal trace placement, the signal trace may be placed on Layer 3, surrounded by ground planes (Layers 2 and 4). This arrangement may help create a balanced transmission line with a consistent characteristic impedance. Regarding one exemplary trace width and spacing, the appropriate trace width and spacing may be calculated based on the desired characteristic impedance for the stripline. The trace width and spacing should be consistent to maintain the desired impedance. Regarding one exemplary ground plane stitching, there should be proper stitching vias between the ground planes (Layers 2 and 4) around the signal trace to maintain a continuous ground reference. These vias may help reduce electromagnetic interference and provide a solid ground plane for the stripline. Regarding via placement, the vias may be placed at regular intervals along the signal trace to maintain the desired impedance and minimize signal degradation. These vias connect the adjacent ground planes to maintain a controlled path and isolation around the signal. Regarding isolation between striplines, adequate spacing and isolation between adjacent striplines should be ensured to minimize crosstalk. The separation helps reduce electromagnetic coupling and interference between signals traveling on different traces. Regarding one exemplary instance impedance matching, impedance-matching techniques may be used to achieve the desired characteristic impedance for the stripline. This might include adjusting the trace width, dielectric thickness, and layer spacing. Regarding shielded connectors, shielded connectors may be used at the input and output of the stripline to maintain the shielding effect and prevent external interference from affecting the transmitted signal.

In another example, improved signal coupling and noise reduction may be accomplished by a combination of tightly and loosely coupling and adjusted routing for pinfields on the backplanes 12. Employing the adjusted routing for pinfields aids in a more producible backplane with realistic routing rules while reducing reflections and the potential to increase isolation. This ensures that signals are properly coupled where needed and minimizes unwanted coupling, contributing to improved signal quality across backplanes 12 in assembly 10.

In another example, improved signals integrity and cost reduction may be accomplished by the removal of non-functional pads. It decreases unwanted coupling in the layout and allows for a more manufacturable printed circuit board 12 as part of a system 10.

As detailed herein, the present disclosure provides for the selective electrical connection of the first backplane 12A with the second backplane 12B (or any other number of backplanes in assembly 10, such third backplane 12C and others). Remarkably, connecting two or more backplanes 12 via a cable, flexprint or wire 20 between their respective electrical connectors 16 is different from connecting a backplane to a motherboard or daughter card due to the nature of the connection, the purpose, and the involved hardware. When connecting a backplane to itself, or two backplanes together, such as what is taught by the present disclosure, the connection is typically a point-to-point or direct cable connection between the respective connectors 16 on each backplane. This connection is established to facilitate communication and data transfer between the modules 14 integrated by these backplanes. This is distinguishable from a connection between a backplane and a motherboard or daughter card that involves a more integrated and standardized approach that utilizes specific slots or connectors on the backplane, whose connections are not changeable, to securely interface with corresponding connectors on the motherboard or daughter card.

Further, connecting a backplane 12 to itself, or two or more backplanes 12 together, such as what is taught herein via a cable or wire 20 between their respective electrical connectors 16, directly allows for interconnecting multiple modules 14 or devices in a modular or scalable manner. It supports expanding the capabilities of one backplane or module by leveraging the resources where specifically needed, or leveraging resources of another. Conversely, the connection between a backplane and a motherboard or daughter card serves to integrate essential components and functionalities within a single system which enables components like processors, memory, I/O modules, and expansion cards to communicate and work together.

Still further, connecting multiple backplanes in the manner of the examples of the present disclosure enhances modularity and scalability of assembly 10 by allowing systems or modules 14 to be extended or combined, often in rack-mounted or chassis-based configurations. Conversely, the connection between a backplane and a motherboard or daughter card contributes to the overall modularity of the entire system (i.e., not modularity and scalability of the assembly 10). Different components can be replaced, upgraded, or added to meet specific requirements. The overall scalability of a daughtercard or motherboard into a backplane system is limited by the number of slots present. With the reconfigurable connectors in the described system, the backplane 12 to backplane 12 system 10 is potentially infinitely configurable with the addition of additional backplanes 12 or systems 10 by cable 20. The system is limited to the ways in which your hardware parts will interact with each other.

Additionally, the connection between a single backplane or multiple backplanes is more ad-hoc and specialized, often tailored to the specific system architecture and requirements. It may involve custom cabling and connectors. Conversely, the connection between a backplane and a motherboard or daughter card follows fixed interfaces and slots, ensuring compatibility and interoperability based on industry standards like PCIe, SATA, etc.

Thus, according to exemplary aspects of the present disclosure, it can be seen that connecting one backplane to itself or two or more backplanes 12 directly via a cable or wire 20 involves a specialized, ad-hoc point-to-point connection to interconnect different modules or devices. Conversely, the present disclosure is distinctive and different from connecting a backplane to a motherboard or daughter card that follows fixed interfaces, slots, and connectors, integrating critical components within a single system.

Exemplary modules 14 can vary depending on the specific computer system or device within which assembly 10 is installed or to be used. For example, one exemplary module 14 could be a Graphics Card (GPU) Module. Regarding the physical connection to the backplane 12, a graphics card is a common module that enhances the video rendering capabilities of a computer. It is physically connected to a slot on the backplane 12, typically using a PCIe (Peripheral Component Interconnect Express) slot. The card securely fits into the slot and is secured with screws or locking mechanisms. Regarding the operation on the backplane for this module 14, the graphics card module interfaces with the backplane 12 via a slot, such as a PCIe slot. The PCIe slot provides the necessary power and high-speed data transfer paths to the graphics card. The backplane 12 acts as an intermediary, facilitating communication between the graphics card and the motherboard/CPU. Data for rendering graphics is transferred between the CPU and the GPU through the backplane, enabling display output on the monitor. The signals or data generated from this module maybe transferred along cables, flexprint or wires 20 to another module on the same backplane or another backplane to allow different modules to share resources and information contained in the signal or the data of the signal. Alternatively, signals or data generated form a different module on this same backplane or another backplane maybe received along cables, flexprint or wires 20 to allow different modules to share resources and information contained in the signal or data of the signal.

Alternatively, another exemplary module 14 could be a Network Interface Card (NIC) Module. Regarding the physical connection of this exemplary module 14 to the backplane, a NIC module is used for network connectivity. It physically connects to the backplane 12 through a PCIe slot or other supported slot types. The NIC module is secured in place once inserted into the appropriate slot. Regarding the operation on the this module on the backplane 12, the NIC module operates by connecting to the backplane 12, which in turn provides connectivity to the CPU within which assembly 10 is installed. It allows the assembly 10 to send and receive data over a network. The backplane 12 manages data transmission between the NIC and the CPU, ensuring efficient network communication. The signals or data generated from this module maybe transferred along cables, flexprint or wires 20 to another module on the same backplane or another backplane to allow different modules to share resources and information contained in the signal or the data of the signal. Alternatively, signals or data generated form a different module on this same backplane or another backplane maybe received along cables, flexprint or wires 20 to allow different modules to share resources and information contained in the signal or data of the signal.

Alternatively, another exemplary module 14 could be a Storage Controller Module. Regarding the physical connection of this exemplary module 14 to the backplane 12, a storage controller module, such as a RAID (Redundant Array of Independent Disks) controller, physically connects to the backplane 12 through a supported slot like a PCIe slot or a dedicated storage slot. Regarding the operation of this exemplary module 14 on the backplane 12, the storage controller module interfaces with the backplane 12 to manage storage devices connected to the system. It allows for efficient data access, storage management, and RAID configurations. The backplane 12 facilitates communication between the storage controller module and the CPU/motherboard, ensuring seamless data transfer between the controller and storage devices. The signals or data generated from this module maybe transferred along cables, flexprint or wires 20 to another module on the same backplane or another backplane to allow different modules to share resources and information contained in the signal or the data of the signal. Alternatively, signals or data generated form a different module on this same backplane or another backplane maybe received along cables, flexprint or wires 20 to allow different modules to share resources and information contained in the signal or data of the signal.

Alternatively, another exemplary module could be a Memory Module (RAM). Regarding the physical connection of this exemplary module 14 to the backplane 12, RAM modules are a fundamental type of memory used in computers. RAM modules are inserted into dedicated memory slots on the backplane 12. Regarding the operation of this exemplary module 14 on the backplane, the memory modules facilitate communication between the memory modules and the CPU, enabling rapid data access and retrieval. The CPU interacts with the memory through the backplane, ensuring efficient memory operations during computing tasks. The signals or data generated from this module maybe transferred along cables, flexprint or wires 20 to another module on the same backplane or another backplane to allow different modules to share resources and information contained in the signal or the data of the signal. Alternatively, signals or data generated form a different module on this same backplane or another backplane maybe received along cables, flexprint or wires 20 to allow different modules to share resources and information contained in the signal or data of the signal.

In one particular example, the plurality of modules 14 on either the first backplane 12A or the second backplane 12B (or any other number of backplanes) are electronic warfare (EW) modules. The EW modules are components used in military and defense applications to counter or exploit electromagnetic spectrum threats. These modules are designed to enhance situational awareness, protect against electronic attacks, and conduct electronic countermeasures. Some exemplary EW modules 14 that may be mounted on one or more of the backplanes 12 in an EW system include, but are not limited to the following. The signals or data generated from this module maybe transferred along cables, flexprint or wires 20 to another module on the same backplane or another backplane to allow different modules to share resources and information contained in the signal or the data of the signal. Alternatively, signals or data generated form a different module on this same backplane or another backplane maybe received along cables, flexprint or wires 20 to allow different modules to share resources and information contained in the signal or data of the signal.

An exemplary electronic countermeasures (ECM) module 14 can be designed in assembly 10 to disrupt, deceive, or neutralize enemy radar and communication systems by emitting electronic signals. It may generate false targets, noise, or other interference to confuse or mislead the adversary's electronic sensors. The ECM module 14 would connect to either one or both of the backplanes 12 using specialized connectors and slots, often designed for military-grade standards. The signals or data generated from this module maybe transferred along cables, flexprint or wires 20 to another module on the same backplane or another backplane to allow different modules to share resources and information contained in the signal or the data of the signal. Alternatively, signals or data generated form a different module on this same backplane or another backplane maybe received along cables, flexprint or wires 20 to allow different modules to share resources and information contained in the signal or data of the signal.

An exemplary electronic support measures (ESM) module 14 can be used in assembly 10 used to passively detect and analyze enemy electromagnetic emissions, such as radar signals or communication transmissions. It provides information about the adversary's activities and capabilities. The ESM modules would connect to either one or both of the backplane for data processing, analysis, and integration with other components of the EW system. The signals or data generated from this module maybe transferred along cables, flexprint or wires 20 to another module on the same backplane or another backplane to allow different modules to share resources and information contained in the signal or the data of the signal. Alternatively, signals or data generated form a different module on this same backplane or another backplane maybe received along cables, flexprint or wires 20 to allow different modules to share resources and information contained in the signal or data of the signal.

An exemplary direction finding (DF) module 14 can be used in assembly 10 to determine the direction of the source of electromagnetic signals, such as radars or communication transmissions. It helps in locating and identifying enemy emitters. The DF module would connect to either one or both of the backplanes 12 for data processing, analysis, and integration with other EW components. The signals or data generated from this module maybe transferred along cables, flexprint or wires 20 to another module on the same backplane or another backplane to allow different modules to share resources and information contained in the signal or the data of the signal. Alternatively, signals or data generated form a different module on this same backplane or another backplane maybe received along cables, flexprint or wires 20 to allow different modules to share resources and information contained in the signal or data of the signal.

An exemplary jamming transmitter module 14 can be used in assembly 10 to emit powerful electronic signals in specific frequencies to overwhelm or disrupt the enemy's electronic systems, such as radars or communication devices. This module would connect to either one or both of the backplanes 12 for power supply, control, and coordination with other EW modules. The signals or data generated from this module maybe transferred along cables, flexprint or wires 20 to another module on the same backplane or another backplane to allow different modules to share resources and information contained in the signal or the data of the signal. Alternatively, signals or data generated form a different module on this same backplane or another backplane maybe received along cables, flexprint or wires 20 to allow different modules to share resources and information contained in the signal or data of the signal.

An exemplary signal intelligence (SIGINT) module 14 could be used in assembly 10 to intercept and analyze various electronic signals to gather intelligence, detect patterns, and identify potential threats or vulnerabilities. The SIGINT module connects to either one or both of the backplanes 12 for data processing, analysis, and integration with other EW components. The signals or data generated from this module maybe transferred along cables, flexprint or wires 20 to another module on the same backplane or another backplane to allow different modules to share resources and information contained in the signal or the data of the signal. Alternatively, signals or data generated form a different module on this same backplane or another backplane maybe received along cables, flexprint or wires 20 to allow different modules to share resources and information contained in the signal or data of the signal.

An exemplary frequency hopping module 14 can be used in assembly 10 to rapidly change frequencies in a coordinated manner to avoid detection or jamming attempts by adversaries. This technique enhances communication security. The frequency hopping module would connect to either one or both the backplanes 12 for synchronization and coordination with other EW modules and communication systems. The signals or data generated from this module maybe transferred along cables, flexprint or wires 20 to another module on the same backplane or another backplane to allow different modules to share resources and information contained in the signal or the data of the signal. Alternatively, signals or data generated form a different module on this same backplane or another backplane maybe received along cables, flexprint or wires 20 to allow different modules to share resources and information contained in the signal or data of the signal.

Notably, these exemplary EW modules are different than conventional networking modules in terms of their intended purpose, functionality, design, and operational objectives. The exemplary EW modules detailed herein have a different purpose and functionality than conventional networking modules. Namely, the exemplary EW modules are designed for military and defense applications to enhance situational awareness, protect against electronic threats, and conduct electronic countermeasures. They involve activities such as jamming enemy radar systems, intercepting electronic signals for intelligence, and determining the direction of electronic emissions. Conversely, conventional networking modules, on the other hand, are intended to enable communication and data transfer within a network. They facilitate tasks like data routing, switching, and transmission, allowing devices to communicate and share information over a network.

The exemplary EW modules 14 detailed herein have different operational purposes or objectives than networking modules. Namely, EW modules aim to disrupt or exploit the adversary's electronic systems, providing tactical advantages and protection to friendly forces. They contribute to mission success by countering enemy electronic capabilities and gathering critical intelligence. Conversely, networking modules focus on establishing reliable and efficient communication pathways within a network, ensuring that data is transmitted accurately and efficiently between devices.

The exemplary EW modules 14 detailed herein have different signal processing and analysis than networking modules. Namely, EW modules involve complex signal processing, analysis, and manipulation to identify, intercept, and respond to electronic threats effectively. They often employ advanced algorithms and techniques to detect, analyze, and mitigate electronic warfare threats. Conversely, networking modules primarily focus on signal routing, switching, and basic processing to direct data packets across a network. Their functions are geared towards efficient data transfer rather than sophisticated signal analysis. The signals or data generated from this module maybe transferred along cables, flexprint or wires 20 to another module on the same backplane or another backplane to allow different modules to share resources and information contained in the signal or the data of the signal. Alternatively, signals or data generated form a different module on this same backplane or another backplane maybe received along cables, flexprint or wires 20 to allow different modules to share resources and information contained in the signal or data of the signal.

The exemplary EW modules 14 detailed herein have different electromagnet spectrum utilization than networking modules. Namely, EW modules actively manipulate the electromagnetic spectrum to disrupt or deceive enemy systems. This can include jamming frequencies, detecting signals, or emitting deceptive signals. Conversely, networking modules manage data flow within the existing electromagnetic spectrum, optimizing data transfer, minimizing collisions, and ensuring reliable communication. The signals or data generated from this module maybe transferred along cables, flexprint or wires 20 to another module on the same backplane or another backplane to allow different modules to share resources and information contained in the signal or the data of the signal. Alternatively, signals or data generated form a different module on this same backplane or another backplane maybe received along cables, flexprint or wires 20 to allow different modules to share resources and information contained in the signal or data of the signal.

The exemplary EW modules 14 detailed herein have different physical design and components than networking modules. Namely, EW modules are designed to withstand harsh military environments, electromagnetic interference, and potentially hostile conditions. They often have ruggedized designs and materials to ensure durability and reliability in combat situations. Conversely, conventional networking modules are designed for civilian or controlled environments, focusing on performance and efficiency without the need for the same level of ruggedization and durability as EW modules. The signals or data generated from this module maybe transferred along cables, flexprint or wires 20 to another module on the same backplane or another backplane to allow different modules to share resources and information contained in the signal or the data of the signal. Alternatively, signals or data generated form a different module on this same backplane or another backplane maybe received along cables, flexprint or wires 20 to allow different modules to share resources and information contained in the signal or data of the signal.

Having thus described the difference between EW modules and networking modules, it should be appreciated to one having ordinary skill in the art that swapping networking modules for EW modules on a backplane is not straightforward due to several critical reasons related to their specific functionalities, hardware compatibility, operational objectives, and system requirements. Namely, networking modules and EW modules serve vastly different purposes and have unique functionalities. Networking modules facilitate communication, data routing, and packet processing, while EW modules are designed for electronic warfare activities such as signal interception, jamming, and analysis. The distinct operational objectives and functionalities make a direct swap impractical and ineffective. Additionally, networking modules are designed to work within specific networking standards and protocols, such as Ethernet, TCP/IP, and UDP. Conversely, EW modules have specialized hardware and operate using military-grade communication protocols tailored for electronic warfare applications. The hardware and protocol incompatibility make it challenging to swap these modules without extensive modifications or redesign. Further, EW modules require specialized hardware and signal processing capabilities to manipulate the electromagnetic spectrum, detect signals, and perform electronic countermeasures. Networking modules are not equipped to handle these specialized signal processing requirements, making them unsuitable for EW applications. Still further, EW modules typically have higher power consumption and different cooling needs compared to networking modules. The backplane needs to support the power and cooling requirements specific to the type of modules being used. Swapping modules without ensuring compatibility with power and cooling systems can lead to inadequate performance or even damage to the modules or backplane. Additionally, networking modules are designed to seamlessly integrate into networking infrastructures and work with a wide range of networking devices. EW modules, however, require specific integration into military-grade EW systems, including interoperability with other defense systems and components. Achieving this level of integration is complex and not straightforward. Thus the inherent differences in functionality, hardware, protocols, power requirements, and integration complexities between networking and EW modules may make it impractical to simply swap one for the other on a backplane without extensive modifications, redesign, and testing.

The exemplary electric connectors 16 may be high-speed connectors. High-speed connectors 16 or connections between modules 14 are facilitated fast and efficient data transfer and communication within a computer system. These connectors 16 are useful for maintaining high bandwidth, low latency, and reliable connections between modules 14. Some exemplary high-speed connections include but are not limited to: PCI Express (PCIe)—PCIe is a widely used high-speed serial computer expansion bus standard. It offers high-speed data transfer rates and low latency, making it suitable for connecting various modules like graphics cards, storage controllers, network cards, and more; Serial Attached SCSI (SAS)—SAS is a high-speed, serial communication protocol designed for connecting storage devices such as hard drives, SSDs, and tape drives. It offers high data transfer rates and is used in enterprise-grade storage solutions; Serial Advanced Technology Attachment (SATA)—SATA is a high-speed interface primarily used for connecting storage devices such as hard drives and SSDs to the motherboard. It offers fast data transfer rates, especially in its latest versions like SATA III; InfiniBand—InfiniBand is a high-speed interconnect used in high-performance computing (HPC) and enterprise environments. It provides high bandwidth and low latency, making it suitable for connecting servers, storage, and networking equipment; HyperTransport—HyperTransport is a high-speed, point-to-point interconnect standard primarily used for connecting CPUs, memory controllers, and other high-speed devices. It is commonly used in server and workstation environments; FireWire (IEEE 1394)—FireWire is a high-speed serial bus interface that was commonly used for connecting external devices like digital cameras, external hard drives, and audio interfaces. While it has been largely replaced by newer standards, it still finds some specialized uses; USB (Universal Serial Bus)—USB is a versatile high-speed interface used for connecting a wide range of peripherals to a computer, including storage devices, printers, cameras, and more. USB 3.0 and later versions offer significantly higher data transfer rates; Thunderbolt—Thunderbolt is a high-speed interface that supports both data transfer and video connectivity. It allows for the daisy-chaining of multiple devices and offers extremely high data transfer rates, making it suitable for various applications, including connecting external storage and displays; Ethernet (RJ45)—Ethernet is a widely used standard for local area networking (LAN). It provides high-speed connectivity for data transfer and is commonly used to connect modules in networking equipment; Optical Fiber Connectors—Fiber optic connectors, such as LC, SC, and MTP/MPO connectors, are used for high-speed optical communication between modules. They offer high bandwidth, low latency, and are resistant to electromagnetic interference; or MLVDS, RS-485, Ethernet, or serializer/deserializer (SERDES), or the like. While the foregoing high-speed connections are exemplary, it is noteworthy that any type of currently available or future available high-speed connection is plausible.

The cables, flexprint or wires 20 that are used to connect the backplanes 12A, 12B electrically via connectors 16 can be achieved using various types of cables or wires, depending on the specific requirements of the system. Some exemplary embodiments of cables or wires 20 may include a ribbon cable that is a flat, flexible cable with multiple conducting wires running parallel to each other. It's suitable for connecting two backplanes with adjacent connectors. Additionally, coaxial cables are designed for transmitting high-frequency electrical signals with minimal interference. They have a central conductor surrounded by an insulating layer, a metallic shield, and an outer insulating layer. Coaxial cables are suitable for high-speed data transmission between backplanes. Another type is twisted pair cables having pairs of insulated copper wires twisted together. They are widely used for networking applications and can be used to connect backplanes for communication purposes. Categories like Cat5e, Cat6, or Cat7 are commonly used for various data rates. Another example is differential pair cables designed for high-speed digital signals that provide good noise immunity. They have two parallel conductors with equal and opposite voltages. Differential signaling is common in interfaces like USB, PCIe, and SATA. Another example is a multi-conductor cable that has multiple insulated conductors within a single cable sheath. They are versatile and can carry multiple signals, making them suitable for connecting different signals or modules between backplanes. Yet another example is a flat flexible cable (FFC) that is a thin, flat cable with conductive traces. It is flexible and compact, making it suitable for space-constrained applications where a low-profile and lightweight connection is needed. Another type of communication pathway can be flexprint - a flat flexible epoxy based system where signal and ground paths can be etched into copped fused onto the carrier. Another type is fiber optic cable that uses light signals to transmit data and are ideal for high-speed and long-distance communication between backplanes. They offer high bandwidth, low latency, and immunity to electromagnetic interference. Regardless of which type of cable, flexprint, or wire 20 that is selected for the application specific need of assembly 10, the cable or wire should be able to span the gap 18 between the first backplane 12A and the second backplane 12B. Regardless of which type of cable, flexprint or wire 20 that is selected for the application specific need of assembly 10, the cable, flexprint or wire should be able to route signals to different locations on one singular backplane 12 or to multiple backplanes in a system 10.

The cables, flexprint or wires 20 that are used to connect the backplanes 12A, 12B enables signals from a module on one backplane to be sent to the other backplane (or to another module on the same backplane). When signals are routed via cables, flexprint or wires 20, the other module may receive that signal and utilize it to perform an electronic function or route the signal to a different component for further processing.

As described herein, aspects of the present disclosure may include one or more electrical or other similar secondary components and/or systems therein. The present disclosure is therefore contemplated and will be understood to include any necessary operational components thereof. For example, electrical components will be understood to include any suitable and necessary wiring, fuses, or the like for normal operation thereof. It will be further understood that any connections between various components not explicitly described herein may be made through any suitable means including mechanical fasteners, or more permanent attachment means, such as welding or the like. Alternatively, where feasible and/or desirable, various components of the present disclosure may be integrally formed as a single unit.

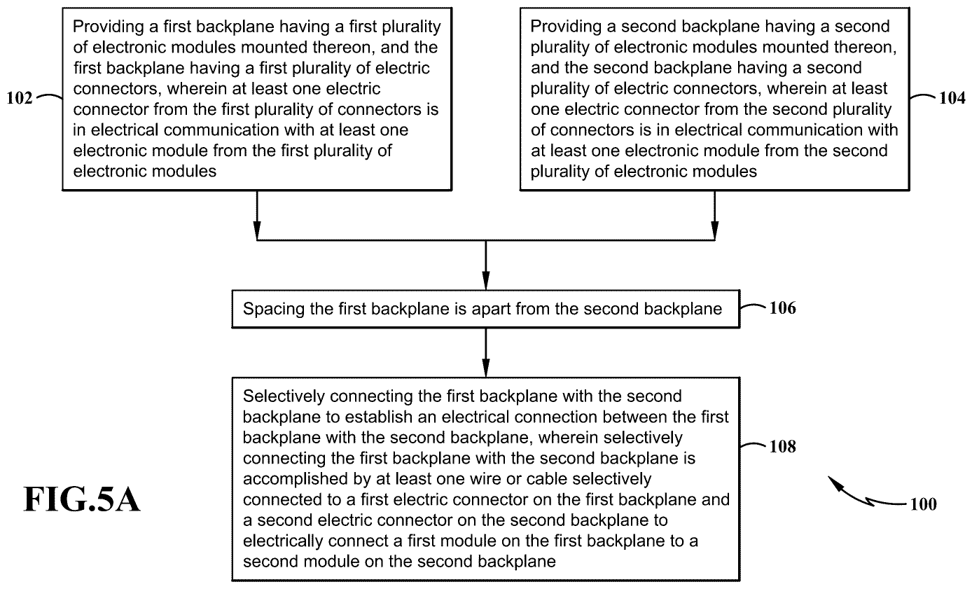

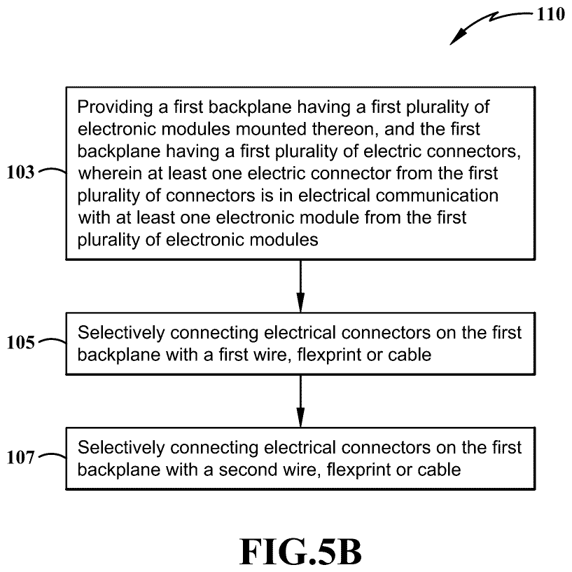

FIG. 5A is a flow chart that depicts an exemplary method of assembling or fabricating the split backplane assembly 10. The method in FIG. 5 is shown generally at 100. Method 100 may include providing the first backplane 12A having the first plurality of electronic modules 14A mounted thereon, and the first backplane 12A having the first plurality of electric connectors 16A, wherein at least one electric connector from the first plurality of connectors 16A is in electrical communication with at least one electronic module from the first plurality of electronic modules 14A, which is shown generally at 102. Method 100 may further include providing the second backplane 12B having a second plurality of electronic modules 14B mounted thereon, and the second backplane having a second plurality of electric connectors 16B, wherein at least one electric connector from the second plurality of connectors 16B is in electrical communication with at least one electronic module from the second plurality of electronic modules 14B, which is shown generally at 104. The method 100 may further include spacing the first backplane 12A apart from the second backplane 12B, which is shown generally at 106. Method 100 may further include selectively connecting the first backplane 12A with the second backplane 12B to establish an electrical connection between the first backplane 12A with the second backplane 12B, wherein selectively connecting the first backplane with the second backplane is accomplished by at least one wire or cable 20 selectively connected to a first electric connector on the first backplane 12A and a second electric connector on the second backplane 12B to electrically connect a first module on the first backplane to a second module on the second backplane, which is shown generally at 108.

FIG. 5B is a flow chart that depicts an exemplary method of assembling or fabricating the split backplane assembly 10. The method in FIG. 5 is shown generally at 110. Method 110 may include providing the first backplane 12A having the first plurality of electronic modules 14A mounted thereon, and the first backplane 12A having the first plurality of electric connectors 16A, wherein at least one electric connector from the first plurality of connectors 16A is in electrical communication with at least one electronic module from the first plurality of electronic modules 14A, which is shown generally at 103. Method 110 may additionally include selectively connecting a first wire, flexprint or cable 20D1 the at least one electric connector 16A1 and another electric connector 16A3 on the first backplane 12A that electrically connects the first electronic module 14A1 on the first backplane with another electronic module 14A3 on the first backplane (i.e., both connectors on the same backplane), which is shown generally at 105. Method 110 may additionally include selectively connecting a second wire, flexprint or cable 20D2 the at least one electric connector 16A and another electric connector 16A2 on the first backplane 12A that electrically connects the first electronic module 14A on the first backplane with another electronic module 14A2 on the first backplane (i.e., both connectors on the same backplane), which is shown generally at 107.

Various inventive concepts may be embodied as one or more methods, of which an example has been provided. The acts performed as part of the method may be ordered in any suitable way. Accordingly, embodiments may be constructed in which acts are performed in an order different than illustrated, which may include performing some acts simultaneously, even though shown as sequential acts in illustrative embodiments.

While various inventive embodiments have been described and illustrated herein, those of ordinary skill in the art will readily envision a variety of other means and/or structures for performing the function and/or obtaining the results and/or one or more of the advantages described herein, and each of such variations and/or modifications is deemed to be within the scope of the inventive embodiments described herein. More generally, those skilled in the art will readily appreciate that all parameters, dimensions, materials, and configurations described herein are meant to be exemplary and that the actual parameters, dimensions, materials, and/or configurations will depend upon the specific application or applications for which the inventive teachings is/are used. Those skilled in the art will recognize, or be able to ascertain using no more than routine experimentation, many equivalents to the specific inventive embodiments described herein. It is, therefore, to be understood that the foregoing embodiments are presented by way of example only and that, within the scope of the appended claims and equivalents thereto, inventive embodiments may be practiced otherwise than as specifically described and claimed. Inventive embodiments of the present disclosure are directed to each individual feature, system, article, material, kit, and/or method described herein. In addition, any combination of two or more such features, systems, articles, materials, kits, and/or methods, if such features, systems, articles, materials, kits, and/or methods are not mutually inconsistent, is included within the inventive scope of the present disclosure.

The above-described embodiments can be implemented in any of numerous ways. For example, embodiments of assembly 10 disclosed herein may be implemented using hardware, firmware, software, or a combination thereof. When assembly 10 is operable with software, the software code or instructions can be executed on any suitable processor or collection of processors, whether provided in a single computer or distributed among multiple computers. Furthermore, the instructions or software code can be stored in at least one non-transitory computer readable storage medium.

Also, a computer or smartphone may be utilized to execute the software code or instructions via its processors may have one or more input and output devices. These devices can be used, among other things, to present a user interface. Examples of output devices that can be used to provide a user interface include printers or display screens for visual presentation of output and speakers or other sound generating devices for audible presentation of output. Examples of input devices that can be used for a user interface include keyboards, and pointing devices, such as mice, touch pads, and digitizing tablets. As another example, a computer may receive input information through speech recognition or in other audible format.

Such computers or smartphones may be interconnected by one or more networks in any suitable form, including a local area network or a wide area network, such as an enterprise network, and intelligent network (IN) or the Internet. Such networks may be based on any suitable technology and may operate according to any suitable protocol and may include wireless networks, wired networks or fiber optic networks.

The various methods or processes outlined herein may be coded as software/instructions that is executable on one or more processors that employ any one of a variety of operating systems or platforms. Additionally, such software may be written using any of a number of suitable programming languages and/or programming or scripting tools, and also may be compiled as executable machine language code or intermediate code that is executed on a framework or virtual machine.

In this respect, various inventive concepts may be embodied as a computer readable storage medium (or multiple computer readable storage media) (e.g., a computer memory, one or more floppy discs, compact discs, optical discs, magnetic tapes, flash memories, USB flash drives, SD cards, circuit configurations in Field Programmable Gate Arrays or other semiconductor devices, or other non-transitory medium or tangible computer storage medium) encoded with one or more programs that, when executed on one or more computers or other processors, perform methods that implement the various embodiments of the disclosure discussed above. The computer readable medium or media can be transportable, such that the program or programs stored thereon can be loaded onto one or more different computers or other processors to implement various aspects of the present disclosure as discussed above.

The terms “program” or “software” or “instructions” are used herein in a generic sense to refer to any type of computer code or set of computer-executable instructions that can be employed to program a computer or other processor to implement various aspects of embodiments as discussed above. Additionally, it should be appreciated that according to one aspect, one or more computer programs that when executed perform methods of the present disclosure need not reside on a single computer or processor, but may be distributed in a modular fashion amongst a number of different computers or processors to implement various aspects of the present disclosure.

Computer-executable instructions may be in many forms, such as program modules, executed by one or more computers or other devices. Generally, program modules include routines, programs, objects, components, data structures, etc. that perform particular tasks or implement particular abstract data types. Typically, the functionality of the program modules may be combined or distributed as desired in various embodiments. As such, one aspect or embodiment of the present disclosure may be a computer program product including at least one non-transitory computer readable storage medium in operative communication with a processor, the storage medium having instructions stored thereon that, when executed by the processor, implement a method or process described herein for the operation of assembly 10, wherein the instructions comprise the steps to perform the method(s) or process(es) detailed herein.

Also, data structures may be stored in computer-readable media in any suitable form. For simplicity of illustration, data structures may be shown to have fields that are related through location in the data structure. Such relationships may likewise be achieved by assigning storage for the fields with locations in a computer-readable medium that convey relationship between the fields. However, any suitable mechanism may be used to establish a relationship between information in fields of a data structure, including through the use of pointers, tags or other mechanisms that establish relationship between data elements.

All definitions, as defined and used herein, should be understood to control over dictionary definitions, definitions in documents incorporated by reference, and/or ordinary meanings of the defined terms.

“Logic”, as used herein, includes but is not limited to hardware, firmware, software, and/or combinations of each to perform a function(s) or an action(s), and/or to cause a function or action from another logic, method, and/or system. For example, based on a desired application or needs, logic may include a software controlled microprocessor, discrete logic like a processor (e.g., microprocessor), an application specific integrated circuit (ASIC), a programmed logic device, a memory device containing instructions, an electric device having a memory, or the like. Logic may include one or more gates, combinations of gates, or other circuit components. Logic may also be fully embodied as software. Where multiple logics are described, it may be possible to incorporate the multiple logics into one physical logic. Similarly, where a single logic is described, it may be possible to distribute that single logic between multiple physical logics.

Furthermore, the logic(s) presented herein for accomplishing various methods of this system may be directed towards improvements in existing computer-centric or internet-centric technology that may not have previous analog versions. The logic(s) may provide specific functionality directly related to structure that addresses and resolves some problems identified herein. The logic(s) may also provide significantly more advantages to solve these problems by providing an exemplary inventive concept as specific logic structure and concordant functionality of the method and system. Furthermore, the logic(s) may also provide specific computer implemented rules that improve on existing technological processes. The logic(s) provided herein extends beyond merely gathering data, analyzing the information, and displaying the results. Further, portions or all of the present disclosure may rely on underlying equations that are derived from the specific arrangement of the equipment or components as recited herein. Thus, portions of the present disclosure as it relates to the specific arrangement of the components are not directed to abstract ideas. Furthermore, the present disclosure and the appended claims present teachings that involve more than performance of well-understood, routine, and conventional activities previously known to the industry. In some of the method or process of the present disclosure, which may incorporate some aspects of natural phenomenon, the process or method steps are additional features that are new and useful.

The articles “a” and “an,” as used herein in the specification and in the claims, unless clearly indicated to the contrary, should be understood to mean “at least one.” The phrase “and/or,” as used herein in the specification and in the claims (if at all), should be understood to mean “either or both” of the elements so conjoined, i.e., elements that are conjunctively present in some cases and disjunctively present in other cases. Multiple elements listed with “and/or” should be construed in the same fashion, i.e., “one or more” of the elements so conjoined. Other elements may optionally be present other than the elements specifically identified by the “and/or” clause, whether related or unrelated to those elements specifically identified. Thus, as a non-limiting example, a reference to “A and/or B”, when used in conjunction with open-ended language such as “comprising” can refer, in one embodiment, to A only (optionally including elements other than B); in another embodiment, to B only (optionally including elements other than A); in yet another embodiment, to both A and B (optionally including other elements); etc. As used herein in the specification and in the claims, “or” should be understood to have the same meaning as “and/or” as defined above. For example, when separating items in a list, “or” or “and/or” shall be interpreted as being inclusive, i.e., the inclusion of at least one, but also including more than one, of a number or list of elements, and, optionally, additional unlisted items. Only terms clearly indicated to the contrary, such as “only one of” or “exactly one of,” or, when used in the claims, “consisting of,” will refer to the inclusion of exactly one element of a number or list of elements. In general, the term “or” as used herein shall only be interpreted as indicating exclusive alternatives (i.e. “one or the other but not both”) when preceded by terms of exclusivity, such as “either,” “one of,” “only one of,” or “exactly one of.” “Consisting essentially of,” when used in the claims, shall have its ordinary meaning as used in the field of patent law.

As used herein in the specification and in the claims, the phrase “at least one,” in reference to a list of one or more elements, should be understood to mean at least one element selected from any one or more of the elements in the list of elements, but not necessarily including at least one of each and every element specifically listed within the list of elements and not excluding any combinations of elements in the list of elements. This definition also allows that elements may optionally be present other than the elements specifically identified within the list of elements to which the phrase “at least one” refers, whether related or unrelated to those elements specifically identified. Thus, as a non-limiting example, “at least one of A and B” (or, equivalently, “at least one of A or B,” or, equivalently “at least one of A and/or B”) can refer, in one embodiment, to at least one, optionally including more than one, A, with no B present (and optionally including elements other than B); in another embodiment, to at least one, optionally including more than one, B, with no A present (and optionally including elements other than A); in yet another embodiment, to at least one, optionally including more than one, A, and at least one, optionally including more than one, B (and optionally including other elements); etc.

While components of the present disclosure are described herein in relation to each other, it is possible for one of the components disclosed herein to include inventive subject matter, if claimed alone or used alone. In keeping with the above example, if the disclosed embodiments teach the features of components A and B, then there may be inventive subject matter in the combination of A and B, A alone, or B alone, unless otherwise stated herein.

As used herein in the specification and in the claims, the term “effecting”or a phrase or claim element beginning with the term “effecting” should be understood to mean to cause something to happen or to bring something about. For example, effecting an event to occur may be caused by actions of a first party even though a second party actually performed the event or had the event occur to the second party. Stated otherwise, effecting refers to one party giving another party the tools, objects, or resources to cause an event to occur. Thus, in this example a claim element of “effecting an event to occur” would mean that a first party is giving a second party the tools or resources needed for the second party to perform the event, however the affirmative single action is the responsibility of the first party to provide the tools or resources to cause said event to occur.

When a feature or element is herein referred to as being “on” another feature or element, it can be directly on the other feature or element or intervening features and/or elements may also be present. In contrast, when a feature or element is referred to as being “directly on” another feature or element, there are no intervening features or elements present. It will also be understood that, when a feature or element is referred to as being “connected”, “attached” or “coupled” to another feature or element, it can be directly connected, attached or coupled to the other feature or element or intervening features or elements may be present. In contrast, when a feature or element is referred to as being “directly connected”, “directly attached” or “directly coupled” to another feature or element, there are no intervening features or elements present. Although described or shown with respect to one embodiment, the features and elements so described or shown can apply to other embodiments. It will also be appreciated by those of skill in the art that references to a structure or feature that is disposed “adjacent” another feature may have portions that overlap or underlie the adjacent feature.

Spatially relative terms, such as “under”, “below”, “lower”, “over”, “upper”, “above”, “behind”, “in front of”, and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if a device in the figures is inverted, elements described as “under” or “beneath” other elements or features would then be oriented “over” the other elements or features. Thus, the exemplary term “under” can encompass both an orientation of over and under. The device may be otherwise oriented (rotated 90 degrees or at other orientations) and the spatially relative descriptors used herein interpreted accordingly. Similarly, the terms “upwardly”, “downwardly”, “vertical”, “horizontal”, “lateral”, “transverse”, “longitudinal”, and the like are used herein for the purpose of explanation only unless specifically indicated otherwise.

Although the terms “first” and “second” may be used herein to describe various features/elements, these features/elements should not be limited by these terms, unless the context indicates otherwise. These terms may be used to distinguish one feature/element from another feature/element. Thus, a first feature/element discussed herein could be termed a second feature/element, and similarly, a second feature/element discussed herein could be termed a first feature/element without departing from the teachings of the present invention.

An embodiment is an implementation or example of the present disclosure. Reference in the specification to “an embodiment,” “one embodiment,” “some embodiments,” “one particular embodiment,” “an exemplary embodiment,” or “other embodiments,” or the like, means that a particular feature, structure, or characteristic described in connection with the embodiments is included in at least some embodiments, but not necessarily all embodiments, of the invention. The various appearances “an embodiment,” “one embodiment,” “some embodiments,” “one particular embodiment,” “an exemplary embodiment,” or “other embodiments,” or the like, are not necessarily all referring to the same embodiments.

If this specification states a component, feature, structure, or characteristic “may”, “might”, or “could” be included, that particular component, feature, structure, or characteristic is not required to be included. If the specification or claim refers to “a” or “an” element, that does not mean there is only one of the element. If the specification or claims refer to “an additional” element, that does not preclude there being more than one of the additional element.

As used herein in the specification and claims, including as used in the examples and unless otherwise expressly specified, all numbers may be read as if prefaced by the word “about” or “approximately,” even if the term does not expressly appear. The phrase “about” or “approximately” may be used when describing magnitude and/or position to indicate that the value and/or position described is within a reasonable expected range of values and/or positions. For example, a numeric value may have a value that is +/−0.1% of the stated value (or range of values), +/−1% of the stated value (or range of values), +/−2% of the stated value (or range of values), +/−5% of the stated value (or range of values), +/−10% of the stated value (or range of values), etc. Any numerical range recited herein is intended to include all sub-ranges subsumed therein.

Additionally, the method of performing the present disclosure may occur in a sequence different than those described herein. Accordingly, no sequence of the method should be read as a limitation unless explicitly stated. It is recognizable that performing some of the steps of the method in a different order could achieve a similar result.

In the claims, as well as in the specification above, all transitional phrases such as “comprising,” “including,” “carrying,” “having,” “containing,” “involving,” “holding,” “composed of,” and the like are to be understood to be open-ended, i.e., to mean including but not limited to. Only the transitional phrases “consisting of” and “consisting essentially of” shall be closed or semi-closed transitional phrases, respectively, as set forth in the United States Patent Office Manual of Patent Examining Procedures.

To the extent that the present disclosure has utilized the term “invention”in various titles or sections of this specification, this term was included as required by the formatting requirements of word document submissions pursuant the guidelines/requirements of the United States Patent and Trademark Office and shall not, in any manner, be considered a disavowal of any subject matter.

In the foregoing description, certain terms have been used for brevity, clearness, and understanding. No unnecessary limitations are to be implied therefrom beyond the requirement of the prior art because such terms are used for descriptive purposes and are intended to be broadly construed.

Moreover, the description and illustration of various embodiments of the disclosure are examples and the disclosure is not limited to the exact details shown or described.

What is claimed is:

1. A split backplane assembly comprising:
a first backplane having a first plurality of electronic modules mounted thereon, and the first backplane having a first plurality of electric connectors, wherein at least one electric connector from the first plurality of connectors is in electrical communication with at least one electronic module from the first plurality of electronic modules;
a second backplane having a second plurality of electronic modules mounted thereon, and the second backplane having a second plurality of electric connectors, wherein at least one electric connector from the second plurality of connectors is in electrical communication with at least one electronic module from the second plurality of electronic modules;
wherein the first backplane is physically spaced apart from the second backplane;
wherein the first backplane is in selective electrical communication with the second backplane via at least one wire, flexprint or cable selectively connected to a first electric connector on the first backplane and a second electric connector on the second backplane that electrically connects a first module on the first backplane to a second module on the second backplane.

2. The split backplane assembly of claim 1, further comprising:
a first electrical configuration in which the at least one wire, flexprint or cable is connected to the first electric connector on the first backplane and the second electric connector on the second backplane;
a second electrical configuration in which the at least one wire, flexprint or cable is connected to the first electric connector on the first backplane and another second electric connector on the second backplane;
wherein whether the split backplane assembly is in the first electrical configuration or the second electrical configuration is based on user-selected preference.

3. The split backplane assembly of claim 1, further comprising:
a third backplane having a third plurality of electronic modules mounted thereon, and the third backplane having a third plurality of electric connectors, wherein at least one connector from the third plurality of connectors is in electrical communication with at least one electronic module from the third plurality of electronic modules; and
a user selected electrical communication between the first backplane and at least one of the second backplane and the third backplane.

4. The split backplane assembly of claim 3, further comprising:
an electrical configuration in which the at least one wire, flexprint or cable is connected to the first electric connector on the first backplane and the second electric connector on the second backplane, and another at least one wire, flexprint or cable is connected to the second electric connector on the second backplane and a third electric connector on the third backplane;
wherein in this electrical configuration, the at least one electronic module on the first backplane communicates with the at least one electronic module on the third backplane directly by bypassing the second backplane.

5. The split backplane assembly of claim 3, further comprising:
an electrical configuration in which the at least one wire, flexprint or cable is connected to the first electric connector on the first backplane and the second electric connector on the second backplane, and another at least one wire, flexprint or cable is connected to the second electric connector on the second backplane and the third electric connector on the third backplane;
wherein in this electrical configuration, the at least one electronic module on the first backplane communicates with the at least one electronic module on the third backplane indirectly by passing through the at least one module on the second backplane.

6. The split backplane assembly of claim 1, wherein the first backplane is housed within a first housing and the second backplane is housed within a different second housing that is physically distinct from the first housing.

7. The split backplane assembly of claim 1, further comprising:
another wire, flexprint or cable selectively connected between the at least one electric connector and another electric connector on the first backplane that electrically connects the first electronic module on the first backplane with another electronic module on the first backplane.

8. The split backplane assembly of claim 1, wherein the first plurality of electronic modules on the first backplane are electronic warfare (EW) modules.

9. The split backplane assembly of claim 1, wherein at least the first backplane is backdrilled.

10. The split backplane assembly of claim 1, wherein at least the first backplane includes a stripline design configured to achieve a balanced transmission line thereby reducing electromagnetic interference and crosstalk between neighboring traces.

11. A backplane assembly:
a single backplane having a plurality of electronic modules mounted thereon, and the single backplane having a plurality of electric connectors, wherein at least one electric connector from the plurality of connectors is in electrical communication with at least one electronic module from the plurality of electronic modules;
a first electronic module from the plurality of electronic modules, and the first electronic module is in operative communication with a first connector;
a second electronic module from the plurality of electronic modules, and the second electronic module is in operative communication with a second connector;
a third electronic module from the plurality of electronic modules, and the third electronic module is in operative communication with a third connector;
wherein the first electronic module is in user-selected electrical communication with one of the second electronic module and the third electronic module via at least one wire, flexprint or cable selectively connected to the first connector on the first electronic module and one of the second connector and the third connector, wherein user-selection of the communication between the first connector and one of the second connector and the third connector is adjustable based on a desired configuration of the user.

12. A method of fabrication for a split backplane assembly, the method comprising:
providing a first backplane having a first plurality of electronic modules mounted thereon, and the first backplane having a first plurality of electric connectors, wherein at least one electric connector from the first plurality of connectors is in electrical communication with at least one electronic module from the first plurality of electronic modules;
providing a second backplane having a second plurality of electronic modules mounted thereon, and the second backplane having a second plurality of electric connectors, wherein at least one electric connector from the second plurality of connectors is in electrical communication with at least one electronic module from the second plurality of electronic modules;
spacing the first backplane is apart from the second backplane;
selectively connecting the first backplane with the second backplane to establish an electrical connection between the first backplane with the second backplane, wherein selectively connecting the first backplane with the second backplane is accomplished by at least one wire, flexprint or cable selectively connected to a first connector on the first backplane and a second connector on the second backplane to electrically connect a first module on the first backplane to a second module on the second backplane.

13. The method of claim 12, further comprising:
establishing one of:
(i) a first electrical configuration in which the at least one wire, flexprint or cable is connected to the first connector on the first backplane and the second connector on the second backplane; or
(ii) a second electrical configuration in which the at least one wire, flexprint or cable is connected to the first connector on the first backplane and another second connector on the second backplane;
wherein whether the split backplane assembly is in the first electrical configuration or the second electrical configuration is based on user-selected preference.

14. The method of claim 12, further comprising:
providing a third backplane having a third plurality of electronic modules mounted thereon, and the third backplane having a third plurality of electric connectors, wherein at least one connector from the third plurality of connectors is in electrical communication with at least one electronic module from the third plurality of electronic modules; and
establishing a selected electrical communication between the first backplane and at least one of the second backplane and the third backplane.

15. The method of claim 14, further comprising:
establishing the selected electrical configuration in which the at least one wire, flexprint or cable is connected to the first connector on the first backplane and the second connector on the second backplane, and another at least one wire, flexprint or cable is connected to the second connector on the second backplane and the third connector on the third backplane;
wherein when in the selected electrical configuration, the at least one electronic module on the first backplane communicates with the at least one electronic module on the third backplane by one of the following (i) directly by bypassing the second backplane or (ii) indirectly by passing through the at least one module on the second backplane.

16. The method of claim 12, further comprising:
disposing the first backplane within a first housing and disposing the second backplane within a different second housing that is physically distinct from the first housing.

17. The method of claim 12, further comprising:
selectively connecting another wire, flexprint or cable between at least one electric connector and another electric connector on the first backplane that electrically connects the first electronic module on the first backplane with another electronic module on the first backplane.
